(19) United States
(12) Patent Application Publication
(10) Pub. No.: US 2026/0243842 A1
(43) Pub. Date: Aug. 20, 2026

(54) METHOD AND SYSTEM FOR DETECTING DEFECT OF BATTERY IN FORMATION PROCESS

(71) Applicant: SK On Co., Ltd., Seoul (KR)

(72) Inventors: Seung Hoon JUNG, Daejeon (KR); Woo Seop KIM, Daejeon (KR); Joo Eun LEE, Daejeon (KR); Seon Hui CHOI, Daejeon (KR); Kwae Ha KIM, Daejeon (KR); Du Yeon LEE, Daejeon (KR)

(21) Appl. No.: 19/530,383

(22) Filed: Feb. 5, 2026

(30) Foreign Application Priority Data
Feb. 18, 2025 (KR) 10-2025-0020800

(51) Int. Cl. G01R 31/392; G01R 31/385; H01M 10/613; H01M 10/615; H01M 50/609

(52) U.S. Cl. CPC G01R 31/392; G01R 31/3865; H01M 10/613; H01M 10/615; H01M 50/609

(57) ABSTRACT

A method for detecting a defect of a battery in a formation process includes a measurement operation of measuring a voltage of a battery cell during a formation process and an analysis operation of analyzing a difference between a pattern of the voltage and a reference pattern and detecting a defect of the battery cell based on an analysis result, wherein the analysis operation includes analyzing the difference between the pattern of the voltage and the reference pattern in a short time range less than 1 day and a micro voltage range less than 1mV.

### CROSS-REFERENCE TO RELATED APPLICATIONS

This patent document claims the priority and benefits of Korean Patent Application No. 10-2025-0020800 filed on Feb. 18, 2025, the disclosure of which is incorporated herein by reference in its entirety.

### TECHNICAL FIELD

The disclosure and implementations disclosed in this patent document generally relate to a method and system for detecting a defect of a battery in a formation process.

### BACKGROUND

Unlike primary batteries, secondary batteries may be conveniently rechargeable and thus have come to prominence as a power source for various mobile devices and electric vehicles. Such secondary batteries may include a battery cell in which an electrode assembly, which is formed by either stacking or winding a positive electrode plate, a negative electrode plate, and a separator into a roll, is accommodated within a case. A plurality of battery cells may be stacked in a predetermined direction and accommodated in a battery module or battery pack. The battery pack may include a plurality of battery modules.

Detecting battery defects during a battery manufacturing process is crucial for ensuring battery safety. The productivity of the battery manufacturing process may be enhanced by improving the efficiency of battery defect detection.

### SUMMARY

The present disclosure may be implemented in some embodiments to provide a method and system for detecting a defect of a battery in a formation process, capable of efficiently detect defects (e.g., electrical disconnection failures, low voltage failures) of a battery in a formation process (e.g., not only reducing the time required for battery defect detection but also improving battery defect detection performance).

Batteries may be used in eco-friendly electric vehicles, hybrid vehicles, and other vehicles that help ameliorate the effects of climate change by reducing air pollution and greenhouse gas emissions, and therefore, the method and system for detecting a defect of a battery in a formation process according to an embodiment of the present disclosure may also contribute to establishing eco-friendly infrastructure by reducing defects in shipped batteries (e.g., accelerating the establishment of eco-friendly infrastructure and/or preventing environmental pollution caused by defective batteries).

In some embodiments of the present disclosure, a method for detecting a defect of a battery in a formation process includes: a measurement operation of measuring a voltage of a battery cell during a formation process; and an analysis operation of analyzing a difference between a pattern of the voltage and a reference pattern and detecting a defect of the battery cell based on an analysis result, wherein the analysis operation includes analyzing the difference between the pattern of the voltage and the reference pattern in a short time range less than 1 day and a microvoltage range less than 1mV.

The pattern of the voltage may include at least one of a voltage variation during the time range and a voltage slope during the time range, the reference pattern may include at least one of a reference variation and a reference slope, and the analysis operation may include analyzing at least one of a difference between the voltage variation and the reference variation and a difference between the voltage slope and the reference slope.

The analysis operation may include generating information on whether the battery cell is defective, determined based on whether the difference between the voltage variation and the reference variation exceeds a variation error range, the time range may be more than 3 minutes and less than 3 hours, and a maximum value of the variation error range may be less than 0.3mV.

The analysis operation may include generating information as to whether the battery cell is defective, which is determined based on whether the difference between the voltage slope and the reference slope exceeds a slope error range, and a maximum value of the slope error range may be less than 0.1mV/hour.

The measurement operation may include measuring a voltage at a start point and a voltage at an end point of the time range, and the analysis operation may include determining a voltage variation or voltage slope based on a voltage difference between the start point and the end point of the time range.

The method may further include: before the measurement operation, an operation of combining a battery case and battery electrodes and injecting an electrolyte into the battery case to manufacture the battery cell, wherein the time range may be after the operation of manufacturing the battery cell.

The method may further include: a primary charging operation of performing press pre-charging (PPC) or pre-charging on the battery cell; and a secondary charging/discharging operation of performing formation-charging or formation charging/discharging on the battery cell after the primary charging operation, wherein the time range may be after the primary charging operation.

The method may further include: at least one of a primary aging operation of aging the battery cell between the primary charging operation and the secondary charging/discharging operation; and a secondary aging operation of aging the battery cell after the secondary charging/discharging operation, wherein a total aging time of each of the primary aging operation and the secondary aging operation may be less than 1 day, and at least a portion of the time range may overlap a time range of the primary aging operation or a time range of the secondary aging operation.

Each of the primary aging operation and the secondary aging operation may include high-temperature aging of aging the battery cell at a higher temperature than a temperature of the primary charging operation and low-temperature aging of aging the battery cell at a lower temperature than the high temperature, and at least a portion of the time range may overlap the time range of the high-temperature aging and the time range of the low-temperature aging.

In some embodiments of the present disclosure, a system for detecting a defect of a battery in a formation process includes: a measuring device configured to measure a voltage of a battery cell to undergo a formation process; and a controller configured to analyze a difference between a pattern of the voltage and a reference pattern and detect a defect of the battery cell based on an analysis result, wherein the controller analyzes the difference between the pattern of the voltage and the reference pattern within a short time range less than 1 day and a microvoltage range less than 1mV.

The pattern of the voltage may include at least one of a voltage variation during the time range and a voltage slope during the time range, the reference pattern may include at least one of a reference variation and a reference slope, and the controller may analyze at least one of a difference between the voltage variation and the reference variation and a difference between the voltage slope and the reference slope.

The measuring device may measure each of a voltage at a start point and a voltage at an end point of the time range, the controller may generate information on whether the battery cell may be defective, which is determined based on whether the difference between the voltage variation based on a voltage difference between the start point and the end point of the time range and the reference variation exceeds a variation error range, the time range may be more than 3 minutes and less than 3 hours, and a maximum value of the variation error range may be less than 0.3mV.

The measuring device may measure each of a voltage at a start point and a voltage at an end point of the time range, the controller may generate information on whether the battery cell may be defective, which is based on whether a difference between the voltage slope based on a voltage difference between the start point and the end point of the time range and the reference slope exceeds a slope error range, and a maximum value of the slope error range may be less than 0.1mV/hour.

The system may further include: a charger/discharger configured to perform press pre-charging (PPC) or pre-charging on the battery cell, and then perform formation-charging or formation charging/discharging on the battery cell after the PPC or pre-charging, wherein the time range may be after the PPC or pre-charging.

The system may further include: a temperature controller configured to increase or decrease a temperature of the battery cell, wherein the time range may include a time point at which the temperature of the battery cell changes by the temperature controller.

### BRIEF DESCRIPTION OF DRAWINGS

Certain aspects, features, and advantages of the present disclosure are illustrated by the following detailed description with reference to the accompanying drawings.

FIG. 1 is a flowchart illustrating battery processes to which a formation process of a method and system for detecting a defect of a battery in a formation process belongs according to an embodiment of the present disclosure;

FIG. 2 is a flowchart illustrating, in greater detail, the formation process of a method and system for detecting a defect of a battery in a formation process according to an embodiment of the present disclosure;

FIG. 3 is a diagram illustrating a system for detecting a defect of a battery in a formation process according to an embodiment of the present disclosure;

FIG. 4 is a graph illustrating a voltage and temperature of a battery cell over time in a method and system for detecting a defect of a battery in a formation process according to an embodiment of the present disclosure; and

FIG. 5 is a graph illustrating a measured voltage pattern and a reference pattern in a method and system for detecting a defect of a battery in a formation process according to an embodiment of the present disclosure.

### DETAILED DESCRIPTION

Prior to the description of the present disclosure, terms and words used in the present specification and claims to be described below should not be construed as limited to ordinary or dictionary terms, and should be construed in accordance with the technical idea of the present disclosure based on the principle that the inventors may properly define their own disclosures in terms of terms in order to best explain the disclosure.

Also, the same reference numerals or symbols respectively illustrated in the attached drawings denote parts or elements that perform the actually same functions. For convenience of description and understanding, the parts or elements will be described by using the same reference numerals or symbols even in different embodiments.

As used herein, the singular forms are intended to include the plural forms as well, unless the context clearly indicates otherwise. It will be further understood that the terms “comprises,” “comprising,” etc. when used in this specification, specify the presence of stated features, integers, steps, operations, elements, and/or components, but do not preclude the presence or addition of one or more other features, integers, steps, operations, elements, components, and/or groups thereof.

In addition, in the present specification, the expressions, such as an upper side, a lower side, a side face, a rear surface, and the like, are described based on the drawings and may be expressed differently when the direction of the corresponding object is changed.

The terms including ordinal numbers, such as ‘first,’ ‘second,’ etc. may be used herein to distinguish elements from one another. These ordinal numbers are merely used to distinguish the same or similar elements from one another, and meanings of the terms are not construed as being limited by the using of the ordinal numbers. For example, use orders or arrangement orders of elements combined with these ordinal numbers are not limited by numbers thereof. The ordinal numbers may be replaced with one another.

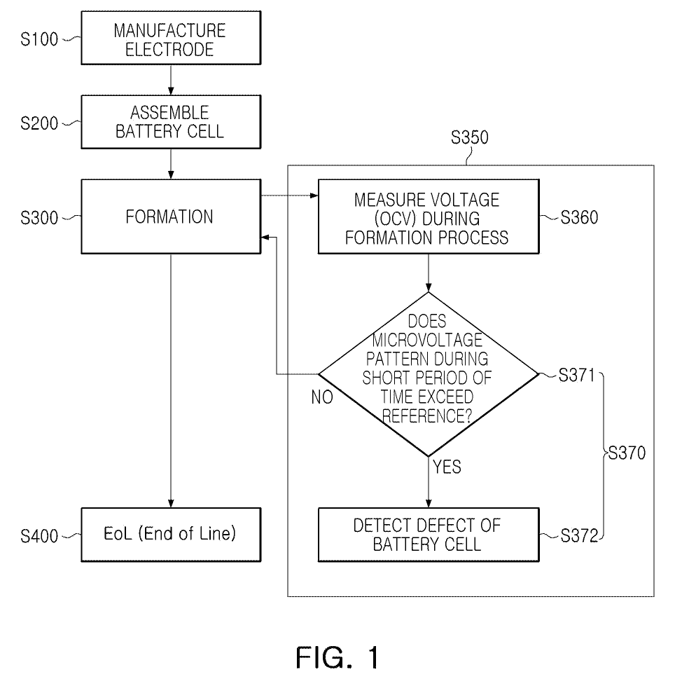

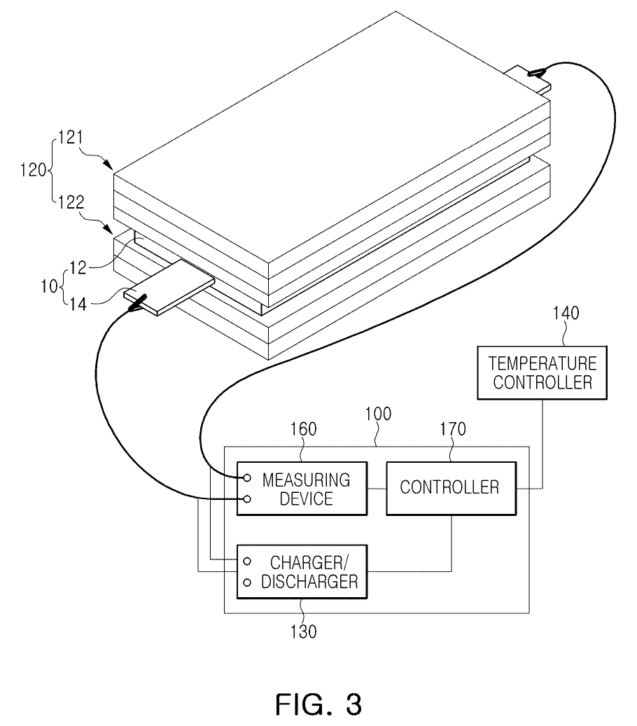

Referring to FIGS. 1 and 3, a formation process (S300) of a method and system for detecting a defect of a battery in a formation process according to an embodiment of the present disclosure may be one of the sequentially performed battery processes (S100, S200, S300, S400). The battery processes may include an electrode manufacturing process (S100), a battery cell assembly process (S200), a formation process (S300), and an end of line (EoL) process (S400). The EoL process may be a post-process for the battery.

The electrode manufacturing process (S100) may include an operation of manufacturing battery electrodes (14 in FIG. 3) of at least one battery cell (10 in FIG. 3). For example, the electrode manufacturing process (S100) may include an operation of forming a slurry by mixing an active material, a conductive agent, a binder, and a solvent, an operation of coating both sides of a positive electrode plate (e.g., an aluminum plate, a copper plate) with a slurry, an operation of rolling the coated positive electrode plate, an operation of forming electrodes by slitting the coated and rolled positive electrode plate, an operation of vacuum-drying the electrodes, and an operation of notching the dried electrodes to manufacture battery electrodes (14 in FIG. 3).

Prior to the formation process (S300) and the measurement operation (S360), the battery cell assembly process (S200) may include an operation of manufacturing a battery cell (10 in FIG. 3) by combining a battery case (12 in FIG. 3) and the battery electrodes (14 in FIG. 3) and injecting an electrolyte into the battery case (12 in FIG. 3) prior to the formation process (S300), and may be included in the method for detecting a defect of a battery in a formation process according to an embodiment of the present disclosure.

For example, the battery cell assembly process (S200) may include an operation of assembling tab-shaped battery electrodes (14 in FIG. 3) and a separator (e.g., a porous polymer film or a porous non-woven fabric) according to a specific method (e.g., at least one of winding, stacking, jelly roll, Z-folding type, and stack-folding), an operation of welding tab-shaped battery electrodes (14 in FIG. 3) to connect positive electrodes or negative electrodes, and an operation of disposing the welded battery electrodes (14 in FIG. 3) within a battery case (12 in FIG. 3) and injecting an electrolyte into the battery case (12 in FIG. 3). The battery case (12 in FIG. 3) may be a pouch-type case including a sealing portion (13 in FIG. 3), but may also be implemented as a cylindrical case or a prismatic case depending on the design.

The formation process (S300) may include an operation of charging at least one battery cell (10 in FIG. 3) assembled by the battery cell assembly process (S200) so that the battery cell has electrical characteristics. During this process, a solid electrolyte interphase layer may be formed on the surface of the negative electrodes of the battery electrodes (14 in FIG. 3), and thus, at least one battery cell (10 in FIG. 3) may have a microscopic structure capable of sustaining continuous electrochemical reactions depending on the voltage of the battery electrodes (14 in FIG. 3).

For example, between the formation process (S300) and the EoL process (S400), a plurality of battery cells (10 in FIG. 3) may be stacked and assembled into a single battery module. For example, a plurality of battery modules may be assembled into a single battery pack or a single battery rack.

The EoL process (S400) may include an inspection operation for at least one battery cell having electrical characteristics following the formation process (S300). For example, the inspection may include at least one of an inspection of electrical performance (e.g., capacity, charge/discharge voltage/current, internal resistance, insulation resistance) of at least one battery cell, temperature sensor performance inspection, battery management system (BMS) performance inspection, and battery cell appearance inspection. Batteries that have completed the EoL process (S400) may be shipped for use in eco-friendly vehicles, such as electric vehicles, or energy storage systems.

For example, quality defects in battery electrodes (14 in FIG. 3) manufactured by the electrode manufacturing process (S100), welding defects within battery cells manufactured by the battery cell assembly process (S200), or equipment defects in the electrode manufacturing process (S100) and battery cell assembly process (S200) may cause defects in the battery cell (10 in FIG. 3). For example, a defect in the battery cell (10 in FIG. 3) may include an electrical disconnection defect within the battery cell (10 in FIG. 3) and/or a low voltage defect, which causes the voltage of the battery cell (10 in FIG. 3) to drop abnormally, and may degrade the lifespan and/or safety of the battery cell (10 in FIG. 3).

Generally, voltage patterns of battery cells left idle for extended periods (e.g., several days) during the formation process may be used to identify battery cell defects (e.g., electrical disconnection defects, low voltage defects). However, leaving battery cells idle for such an extended period (e.g., several days) may act as a limitation in reducing the total duration required for the formation process and may cause an overall decrease in the productivity of the battery manufacturing processes.

Referring to FIGS. 1 and 5, the method for detecting a defect of a battery in a formation process according to an embodiment of the present disclosure may include an operation (S350) of detecting a defect in a battery cell during the formation process (S300), a measurement operation (S360) of measuring the voltage (open circuit voltage OCV) of the battery cell (10 of FIG. 3) during the formation process (S300) using a measuring device (160 of FIG. 3); and an analysis operation (S370) of analyzing the difference between voltage patterns (No. 1, No. 5, No. 8 of FIG. 5) and a reference pattern (Ref of FIG. 5) using a controller (170 of FIG. 3) (S371) and detecting a defect (e.g., electrical disconnection defect, low voltage defect) in the battery cell (10 of FIG. 3) based on the analysis result (S372).

During the formation process (S300), the voltage OCV of a battery cell (10 in FIG. 3) may continuously and minutely decrease. The slope of the voltage OCV drop in a defective battery cell (or the total voltage drop per unit time) may be a value obtained by multiplying the slope of the voltage OCV drop in a good battery cell by a defect weight. The defect weight may be 1 when there are no defect factors in the battery cell (10 in FIG. 3) and may increase as the number of defect factors increases.

Generally, since voltage is analyzed within a large range of mV units or higher during the formation process, that the time required for the voltage OCV of the battery cell (10 in FIG. 3) to continuously and minutely decrease effectively appears in a wide voltage range of mV or higher may be a long period of time (e.g., several days).

That the time required for the voltage OCV of the battery cell (10 in FIG. 3) to continuously and minutely decrease effectively appears in a voltage range less than 1mV may be as short as less than one day. In the analysis operation (S370), the controller (170 in FIG. 3) may analyze the difference between the voltage patterns (No. 1, No. 5, No. 8 of FIG. 5) and the reference pattern (Ref in FIG. 5) in the short time range less than one day and the voltage range less than 1mV.

Accordingly, compared to leaving the battery cell idle for a long period of time (e.g., several days), the total time required for the operation (S350) may be more shortened (e.g., less than one day), thereby improving the overall productivity of battery processes including the formation process (S300).

The horizontal axis of FIG. 5 represents time in minutes (nonlinear units) within the time range (TIME) less than one day, and the vertical axis of FIG. 5 represents the total voltage drop (OCV drop), which is accumulatively dropped, compared to the voltage at measurement start point, within a microvoltage range (microvoltage) less than 1mV.

For example, the reference pattern (Ref) may correspond to a voltage pattern of a substantially defect-free battery cell, and the controller (170 in FIG. 3) may pre-measure the voltage of the substantially defect-free battery cell and store the measured value as the reference pattern (Ref). FIG. 5 illustrates that the total OCV drop of the reference pattern (Ref) is approximately 0.45mV over 120 minutes; however, the specific value of the total OCV drop may vary depending on the model (and/or design specifications) of a substantially defect-free battery cell or a specific measurement timing during the formation process (S300).

For example, the voltage patterns of battery cells subject to defect detection may include a voltage pattern (No. 1) of three good battery cells and voltage patterns (No. 5, No. 8) of three defective battery cells. Under the same conditions as those for obtaining the reference pattern (Ref), the measuring device (160 in FIG. 3) may measure the voltage OCV of the three good battery cells and the three defective battery cells.

For example, the controller (170 in FIG. 3) may analyze that the total voltage drop (OCV Drop) of the voltage pattern (No. 1) of the three good battery cells over 120 minutes falls within the range of 0.46mV to 0.51mV, determine that the voltage pattern (No. 1) shows no significant difference compared to the reference pattern (Ref), and generate information indicating that the three battery cells corresponding to the voltage pattern (No. 1) are good.

For example, the controller (170 in FIG. 3) may analyze that the total voltage drop (OCV Drop) of the voltage patterns (No. 5, No. 8) of three defective battery cells over 120 minutes is in the range of 0.75mV to 0.87mV, analyze that the voltage patterns (No. 5, No. 8) have a significant difference compared to the reference pattern (Ref), and generate information indicating that three battery cells corresponding to the voltage patterns (No. 5, No. 8) are defective.

The formats of the voltage patterns (No. 1, No. 5, No. 8) and the reference pattern (Ref) are not limited to the curves in FIG. 5. For example, the voltage patterns (No. 1, No. 5, No. 8) may include at least one of a voltage variation during the time range (TIME) and a voltage slope during the time range (TIME), and the reference pattern (Ref) may include at least one of a reference variation (e.g., 0.45mV) and a reference slope (e.g., 0.45mV/120 minutes). In the analysis operation (S370), the controller (170 in FIG. 3) may analyze at least one of the difference between the voltage variation (e.g., 0.46mV to 0.51mV, 0.75mV to 0.87mV) and the reference variation (e.g., 0.45mV) and the difference between the voltage slope (e.g., (0.46mV to 0.51mV)/120 minutes, (0.75mV to 0.87mV)/120 minutes) and the reference slope (e.g., 0.45mV/120 minutes). Since the slope of the voltage OCV drop in a defective battery cell (or the total voltage drop per unit time) may be a value obtained by multiplying the slope of the voltage OCV drop in a good battery cell by a defect weight, the variation and the slope may be proportional to the defect weight. The defect weight may be 1 when there are no defect factors in the battery cell (10 in FIG. 3) and may increase as the number of defect factors increases.

For example, in the measurement operation (S360), the measuring device (160 in FIG. 3) may respectively measure the voltages at the start point of the time range (TIME) (e.g., 0 min, after 5 min, 10 min, 30 min, or 60 min) and at the end point (e.g., after 5 min, 10 min, 30 min, 60 min, or 120 min). In the analysis operation (S370), the controller (170 in FIG. 3) may determine a voltage variation (e.g., 0.45mV) or a voltage slope (e.g., 0.45mV/120 min) based on the voltage difference between the start point (e.g., 0 min, after 5 min, 10 min, 30 min, or 60 min) and the end point (e.g., after 5 min, 10 min, 30 min, 60 min, or 120 min) of the time range (TIME).

For example, whether the time range (TIME) is less than one day may be determined based on whether the duration from the first voltage measurement point to the last voltage measurement point by the measuring device (160 in FIG. 3) in the measuring operation (S360) is less than one day.

For example, whether a voltage falls within a microvoltage range less than 1mV may be determined based on whether the difference (including any error range if applicable) between the voltage of the reference pattern (Ref) at the first voltage measurement point and the reference pattern (Ref) at the last voltage measurement point is less than 1mV.

For example, in the analysis operation (S370), the controller (170 in FIG. 3) may generate battery cell defect information based on whether the difference between the voltage variation (e.g., 0.46 mV to 0.51mV, 0.75mV to 0.87mV) and the reference change (e.g., 0.45mV) exceeds a variation error range. For example, the time range (TIME) may be greater than 3 minutes and less than 3 hours, and the maximum value of the variation error range may be less than 0.3mV. A specific variation error range may vary depending on the model (and/or design specifications) of the substantially defect-free battery cell or a specific measurement point in the formation process (S300).

In FIG. 5, since the total voltage drop (OCV Drop) over 120 minutes for the voltage pattern (No. 1) of three good battery cells ranges from 0.46mV to 0.51mV, the difference from the reference variation of 0.45mV for the reference pattern (Ref) may be less than 0.3mV, and the difference may be within the error range. Therefore, in the analysis operation (S370), the controller (170 in FIG. 3) may generate information indicating that the three battery cells corresponding to the voltage pattern (No. 1) are good.

In FIG. 5, since the total voltage drop (OCV Drop) of the voltage patterns (No. 5, No. 8) of three defective battery cells over 120 minutes ranges from 0.75mV to 0.87mV, the difference from the reference variation of 0.45mV for the reference pattern (Ref) may be equal to or greater than 0.3mV, and the difference may exceed the error range. Therefore, in the analysis operation (S370), the controller (170 of FIG. 3) may generate information indicating that three battery cells corresponding to the voltage patterns (No. 5, No. 8) are defective.

For example, in the analysis operation (S370), the controller (170 in FIG. 3) may generate battery cell defect information based on whether the difference between the voltage slope (e.g., (0.46mV to 0.51mV)/120 minutes, (0.75mV to 0.87mV)/120 minutes) and the reference slope (e.g., 0.45mV/120 minutes) exceeds a slope error range. For example, the maximum value of the slope error range may be less than 0.1 (mV/hour). The specific slope error range may vary depending on the model (and/or design specifications) of the substantially defect-free battery cell or a specific measurement point in the formation process (S300).

In FIG. 5, since the average slope of the voltage pattern (No. 1) of three good battery cells over 120 minutes is ((0.23mV to 0.255mV)/hour), the difference from the reference slope (0.225mV/hour) of the reference pattern (Ref) may be less than (0.1mV/hour), and the difference may be within the error range (approximately 0.02mV/hour). Therefore, in the analysis operation (S370), the controller (170 of FIG. 3) may generate information indicating that the three battery cells corresponding to the voltage pattern (No. 1) are good.

In FIG. 5, since the average slope of the voltage patterns (No. 5, No. 8) of three defective battery cells over 120 minutes is ((0.375mV to 0.435 mV)/hour), the difference from the reference slope (0.225mV/hour) of the reference pattern (Ref) may be (0.1mV/hour) or more, and the difference may exceed the error range (approximately 0.2mV/hour). Therefore, in the analysis operation (S370), the controller (170 of FIG. 3) may generate information indicating that three battery cells corresponding to the voltage pattern (No. 5, No. 8) are defective.

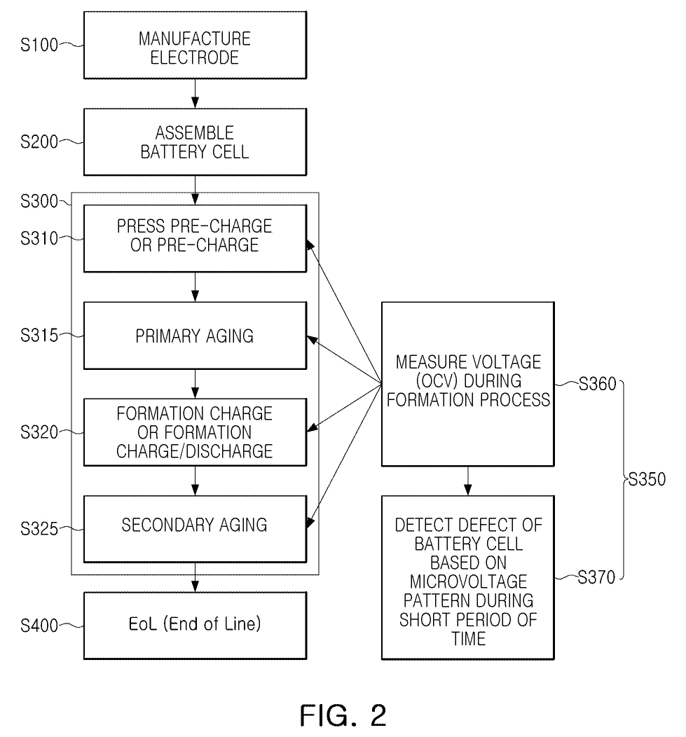

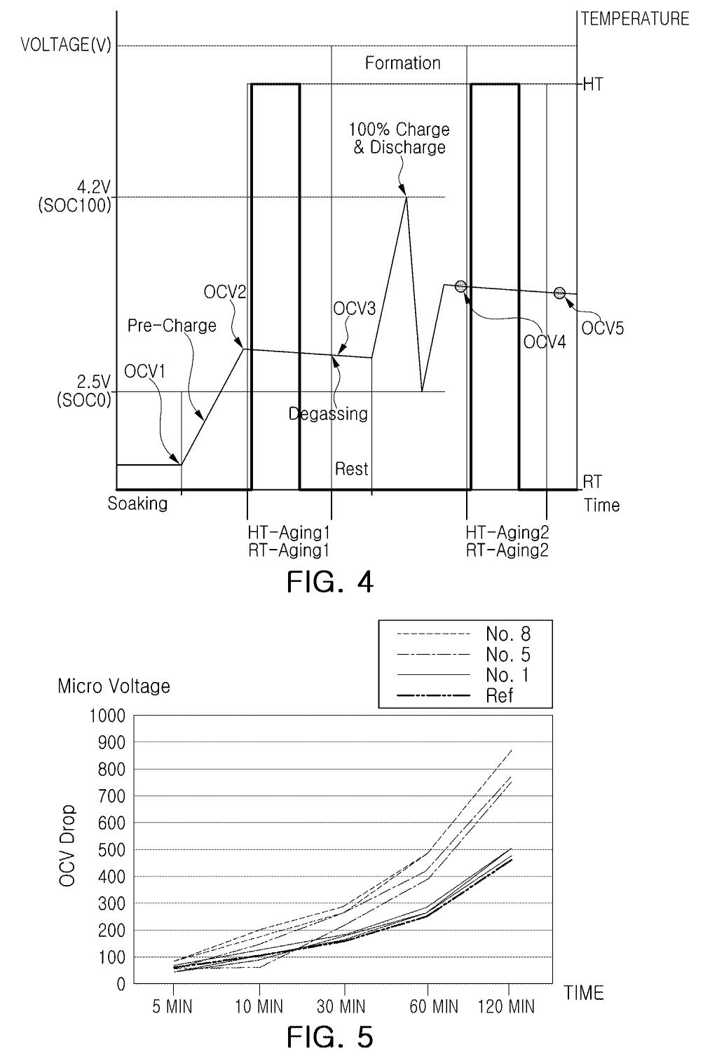

Referring to FIGS. 2 and 4, the method for detecting a defect of a battery in a formation process according to an embodiment of the present disclosure may include a primary charging operation (S310) of performing press pre-charging (PPC) or pre-charging (pre-charging in FIG. 4) on the battery cell (10 of FIG. 3) and may include, following the primary charging operation (S310), a secondary charging/discharging operation (S320) of performing formation charging or formation charging/discharging (100% charge & discharge in FIG. 4) on the battery cell (10 in FIG. 3). PPC (Press Pre-Charge) refers to simultaneously performing both pressing and charging on the battery cell (10 in FIG. 3)

The primary charging operation (S310) may include initially charging the battery cell (10 of FIG. 3) to a predetermined capacity (e.g., 20% to 50%) after the battery cell (10 of FIG. 3) is assembled. At this time, the interior of the battery cell (10 in FIG. 3) may gradually harden. For example, the battery cell (10 in FIG. 3) immediately after the battery cell assembly process (S200) may undergo a soaking process (soaking in FIG. 4), and thereafter, the charger/discharger (130 in FIG. 3) may charge the battery cell (10 in FIG. 3) in a constant current mode, and the voltage of the battery cell (10 in FIG. 3) may gradually increase as the battery cell charges. Depending on the design, the measuring device (160 in FIG. 3) may measure the voltage (OCV1, OCV2 in FIG. 4) of the battery cell (10 in FIG. 3).

For example, in the secondary charge/discharge operation (S320), the charger/discharger (130 in FIG. 3) may charge the battery cell (10 in FIG. 3) to a voltage (e.g., 4.2V) corresponding to a 100% state of charge (SOC), discharge the battery cell to a voltage (e.g., 2.5V) corresponding to a 0% state of charge (SOC), and charge the battery cell to a voltage corresponding to a 60% to 70% state of charge (SOC).

In the measurement operation (S360), a time range measured by the measuring device (160 in FIG. 3) may be subsequent to the battery cell assembly process (S200), which corresponds to the operation of manufacturing the battery cell (e.g., the time corresponding to OCV1, OCV2, OCV3, OCV4, and OCV5 in FIG. 4). The minute and continuous decrease in the voltage OCV of the battery cell may occur immediately after the battery cell (10 in FIG. 3) is assembled.

In the measurement operation (S360), a time range measured by the measuring device (160 in FIG. 3) may be subsequent to the primary charging operation (S310) (e.g., the time corresponding to OCV2, OCV3, OCV4, and OCV5 in FIG. 4). The minute and continuous decrease in the battery cell voltage OCV may occur more distinctly (e.g., with a steeper reference slope) immediately after the primary charging operation (S310), allowing the controller (170 in FIG. 3) to more accurately determine whether the battery cell is defective in the analyzing operation (S370).

Referring to FIGS. 2 and 4, the method for detecting a defect of a battery in a formation process according to an embodiment of the present disclosure may include a primary aging operation (S315) of aging the battery cell (10 of FIG. 3) between the primary charging operation (S310) and the secondary charging/discharging operation (S320) and a secondary aging operation (S325) of aging the battery cell (10 of FIG. 3) after the secondary charging/discharging operation (S320). The aging may involve stopping charging/discharging of the battery cell (10 of FIG. 3) and providing electrical rest to the battery cell (10 of FIG. 3). The total aging time for each of the primary aging operation (S315) and the secondary aging operation (S325) may be less than one day (e.g., 1 minute or more and 10 minutes or less).

For example, a degassing process (degassing in FIG. 4) and a short rest (Rest in FIG. 4) may be performed between the primary aging operation (S315) and the secondary aging operation (S325) and may remove gases (e.g., gases resulting from electrical characteristic formation) generated in the battery cell (10 in FIG. 3) during the primary aging operation (S315). For example, a short rest (Rest) may be implemented by not performing charging and discharging for a time range of 1 minute to 5 minutes, and the time range is not limited.

At least a portion of the time range measured by the measuring device (160 in FIG. 3) in the measuring operation (S360) may overlap the time range (corresponding to HT-Aging1 and RT-Aging1 in FIG. 4) of the primary aging operation (S315) or the time range (corresponding to HT-Aging2 and RT-Aging2 in FIG. 4) of the secondary aging operation (S325). A minute and continuous decrease in the voltage OCV of the battery cell may occur more distinctly (e.g., with the steeper reference slope) in the primary aging operation (S315) and/or the secondary aging operation (S325), and in the analysis operation (S370), the controller (170 in FIG. 3) may more accurately determine whether the battery cell is defective.

For example, in the measurement operation (S360), the measuring device (160 in FIG. 3) may measure the voltage of the battery cell from the second measurement point (OCV2) to the third measurement point (OCV3) in FIG. 4, and the time range from the second measurement point (OCV2) to the third measurement point (OCV3) may overlap the time range (corresponding to HT-Aging1 and RT-Aging1 in FIG. 4) of the primary aging operation (S315).

For example, in the measurement operation (S360), the measuring device (160 in FIG. 3) may measure the voltage of the battery cell from the fourth measurement point (OCV4) to the fifth measurement point (OCV5) in FIG. 4, and the time range from the fourth measurement point (OCV4) to the fifth measurement point (OCV5) may overlap the time range (corresponding to HT-Aging2 and RT-Aging2 in FIG. 4) of the secondary aging operation (S325).

For example, each of the primary aging operation (S315) and the secondary aging operation (S325) may include high- temperature aging (HT-Aging1, HT-Aging2) of aging the battery cell 10 at a high temperature (HT) higher than the temperature of the primary charging operation (S310) and low-temperature aging (RT-Aging1, RT-Aging2) of aging the battery cell 10 at a low temperature (RT) lower than the high temperature (HT). For example, the low temperature (RT) may be room temperature (e.g., 15 degrees Celsius to 30 degrees Celsius) or a temperature (e.g., -10 degrees Celsius to 10 degrees Celsius) lower than the room temperature. For example, the high temperature (HT) may be a temperature (e.g., 40 degrees Celsius to 60 degrees Celsius) higher than the room temperature but is not limited thereto. FIG. 4 illustrates that high-temperature aging (HT-Aging1, HT-Aging2) occurs before low-temperature aging (RT-Aging1, RT-Aging2). However, the order of high-temperature aging (HT-Aging1, HT-Aging2) and low-temperature aging (RT-Aging1, RT-Aging2) is not limited, nor is the number of times the aging is performed limited to 1 or 2.

At least a portion of the time range measured by the measuring device (160 in FIG. 3) in the measuring operation (S360) may overlap the time range (corresponding to HT-Aging1, HT-Aging2 in FIG. 4) of the high-temperature aging and the time range (corresponding to RT-Aging1, RT-Aging2 in FIG. 4) of the low-temperature aging. A minute and continuous decrease in the voltage OCV of the battery cell may occur more distinctly (e.g., with the steeper reference slope) when the temperature of the battery cell 10 changes significantly. In the analysis operation (S370), the controller (170 of FIG. 3) may more accurately determine whether a battery cell is defective.

Referring to FIG. 3, a system for detecting a defect of a battery in a formation process according to an embodiment of the present disclosure may include a measuring device 160 and a controller 170 and may further include at least one of a pressing device 120, a charger/discharger 130, and a temperature controller 140, and may detect defects in the battery cell 10.

For example, the battery cell 10 may be formed by receiving an electrode assembly including a positive electrode plate, a negative electrode plate, and a separator in an outer casing, injecting an electrolyte into the outer casing, and then sealing the outer casing. At this time, electrodes 14 connected to the positive and negative electrode plates, respectively, may be exposed to the outside of the outer casing. The model (type) of the battery cell 10 is not particularly limited. For example, the shape (e.g., pouch-type, prismatic, cylindrical) or material (e.g., lithium iron phosphate (LFP), LiNiMnCoO₂ (NCM), mid-nickel (mid-Ni), high-nickel (high-Ni)) of the battery cell 10 is not particularly limited. Depending on the model (type) of the battery cell 10, the specific data in the graph of FIG. 5 may vary.

The measuring device 160 may be configured to measure the voltage OCV of the battery cell 10 to undergo the formation process (S300 of FIG. 1). For example, the measuring device 160 may be implemented as a digital multi-meter and may include an analog measuring circuit (e.g., a sampling circuit, a buffer circuit, an amplifier circuit, an analog-to-digital conversion circuit). For example, the measuring device 160 may include a sampling circuit repeatedly sampling the voltage of the battery cell 10 at short intervals and may include an envelope detection circuit detecting the voltage trend of the battery cell 10 by frequency analysis (or Fourier transform-based analysis), and a timer (which may also be included in the controller 170) counting time to generate a time value. For example, the measuring device 160 may assign a time value to each of the sampled voltages, may determine whether the voltage of the battery cell rises or falls based on the difference between sampled voltages with adjacent time values, and may calculate the rate of rise/fall (or slope). Depending on the design, the measuring device 160 may perform the determination and/or calculation using only a sampled voltage whose time value falls within a predetermined time range.

The controller 170 may be configured to detect defects (e.g., electrical disconnection defect, low voltage defect) in the battery cell 10 based on the difference between the voltage pattern measured by the measuring device 160 and the reference pattern. For example, the controller 170 may be implemented as a data acquisition system (DAS) and may include a computing system (e.g., a microcontroller, a programmable logic controller (PLC), an embedded system, or a manufacturing execution system (MES)). For example, the computing system may include a processor (e.g., a CPU, a GPU), memory (e.g., volatile memory, non-volatile memory), a recording medium, an input/output device, and a communication device. For example, the controller 170 may operate in a manner in which a processor executes one or more programs (and/or algorithms, logic) recorded in memory or storage, and the operation may correspond to program commands and may correspond to the operations performed by the method for detecting a defect of a battery in a formation process according to an embodiment of the present disclosure. For example, the controller 170 may store the reference pattern in memory and analyze the pattern via the processor.

The temperature controller 140 may be configured to increase and decrease the temperature of the battery cell 10 during a portion of the time (e.g., HT-Aging1 and HT-Aging2 in FIG. 4) while the measuring device 160 measures the voltage OCV of the battery cell 10 (e.g., OCV2 to OCV3 and OCV4 to OCV5 in FIG. 4). The charger/discharger 130 may suspend charging and discharging of the battery cell 10 while the temperature controller 140 increases the temperature. For example, the temperature controller 140 may be implemented to control a structure of heating or cooling the inside of a chamber in which the battery cell 10 is accommodated. Depending on the design, at least a portion (e.g., temperature control logic, etc.) of the temperature controller 140 may be implemented as a controller 170.

In the measurement operation (S360), the time range measured by the measuring device (160 in FIG. 3) may include time points (e.g., both ends of HT-Aging1 and HT-Aging2 in FIG. 4) at which the temperature of the battery cell 10 changes by the temperature controller 140. The minute and continuous decrease in the voltage OCV of the battery cell may occur more distinctly (e.g., with the steeper reference slope) when the temperature of the battery cell 10 changes significantly, and in the analysis operation (S370), the controller (170 in FIG. 3) may more accurately determine whether the battery cell is defective.

The pressing device 120 may apply pressure to the battery cell 10, and the charger/discharger 130 may charge the battery cell 10. For example, the pressing device 120 may be at least part of a press pre-charge (PPS) system. For example, the pressing device 120 may include a plurality of support plates 121 and 122, and the battery cell 10 may be disposed between the plurality of support plates 121 and 122. At this time, the plurality of support plates 121 and 122 may press the battery cell 10 by approaching each other to press the battery cell 10 in a vertical direction.

For example, each of the plurality of support plates 121 and 122 may be implemented in the form of a polyhedron with a flat surface (upper and/or lower surface) facing the battery cell 10 and may press the battery cell 10 by receiving force controlled by the controller 170 in an up-down direction. Depending on the design, the plurality of support plates 121 and 122 may be implemented to move only in the vertical direction, while a horizontal movement is prevented through a fastening member, such as bolts and screws. Depending on the design, the pressing device 120 may be implemented with a roller instead of the plurality of support plates 121 and 122, and the roller may be rolled over one surface of the battery cell 10 to compress the battery cell 10.

For example, the pressure applied by the pressing device 120 to compress the battery cell 10 may be between 0.1MPa and 10MHa (with an error range of +/- 50 kN) and may be non-destructively set so as not to substantially reduce the performance or damage the battery cell 10. The temperature before and after applying pressure to the pressing device 120 may be room temperature (18° C to 28° C), but depending on the design, it may decrease to -10° C or increase to 60° C, but is not limited thereto.

The charger/discharger 130 may pre-charge the battery cell 10 while the pressing device 120 is pressing the battery cell 10 (only when the pressing device 120 is present) and may formation-charge or formation-charge/discharge the battery cell 10 while the pressing device 120 is not pressing the battery cell 10. The measuring device 160 may measure the voltage of the battery cell 10 from a point (e.g., OCV2, OCV3, OCV4, OCV5 of FIG. 4) after the formation-charging of the battery cell 10 or from a point (e.g., OCV4, OCV5 of FIG. 4) after the formation charging/discharging.

For example, the charger/discharger 130 may include a circuit converting commercial AC power into DC power, a circuit (e.g., a regulation circuit, a feedback circuit) controlling the magnitude of DC power current, a power supply, such as a switched mode power supply (SMPS), and a circuit (e.g., a triggering circuit), controlling the output of the DC power current and may be electrically connected to the electrode 14 via a wire (e.g., a power cable), but is not limited thereto.

The method and system for detecting a defect of a battery in a formation process according to an embodiment of the present disclosure may efficiently detect battery defects (e.g., electrical disconnection defect, low voltage defect) during the formation process (e.g., reducing the time required for detecting a battery defect and improving battery defect detection performance).

For example, the process of leaving battery cells idle in the formation process for extended periods of time (e.g., several days) to detect defects (e.g., electrical disconnection defect, low voltage defect) in the battery cells may be omitted.

Only specific examples of implementations of certain embodiments are described. Variations, improvements and enhancements of the disclosed embodiments and other embodiments may be made based on the disclosure of this patent document.

What is claimed is:

1. A method for detecting a defect of a battery in a formation process, the method comprising:
a measurement operation of measuring a voltage of a battery cell during a formation process; and
an analysis operation of analyzing a difference between a pattern of the voltage and a reference pattern and detecting a defect of the battery cell based on an analysis result,
wherein the analysis operation includes analyzing the difference between the pattern of the voltage and the reference pattern in a short time range less than 1 day and a micro voltage range less than 1mV.

2. The method of claim 1, wherein
the pattern of the voltage includes at least one of a voltage variation during the time range or a voltage slope during the time range,
the reference pattern includes at least one of a reference variation or a reference slope, and
the analysis operation includes analyzing at least one of a difference between the voltage variation and the reference variation or a difference between the voltage slope and the reference slope.

3. The method of claim 2, wherein
the analysis operation includes generating information on whether the battery cell is defective, which is determined based on whether the difference between the voltage variation and the reference variation exceeds a variation error range,
the time range is more than 3 minutes and less than 3 hours, and
a maximum value of the variation error range is less than 0.3mV.

4. The method of claim 2, wherein the analysis operation includes generating information on whether the battery cell is defective, which is determined based on whether the difference between the voltage slope and the reference slope exceeds a slope error range, and
a maximum value of the slope error range is less than 0.1 (mV/hour).

5. The method of claim 1, wherein
the measurement operation includes measuring a voltage at a start point and a voltage at an end point of the time range, and
the analysis operation includes determining a voltage variation or voltage slope based on a voltage difference between the start point and the end point of the time range.

6. The method of claim 1, further comprising:
before the measurement operation, an operation of combining a battery case and battery electrodes and injecting an electrolyte into the battery case to manufacture the battery cell,
wherein the time range is after the operation of manufacturing the battery cell.

7. The method of claim 1, further comprising:
a primary charging operation of performing press pre-charging (PPC) or pre-charging on the battery cell; and
a secondary charging/discharging operation of performing formation-charging or formation charging/discharging on the battery cell after the primary charging operation,
wherein the time range is after the primary charging operation.

8. The method of claim 7, further comprising at least one of:
a primary aging operation of aging the battery cell between the primary charging operation and the secondary charging/discharging operation; or
a secondary aging operation of aging the battery cell after the secondary charging/discharging operation,
wherein a total aging time of each of the primary aging operation and the secondary aging operation is less than 1 day, and
at least a portion of the short time range overlaps a time range of the primary aging operation or a time range of the secondary aging operation.

9. The method of claim 8, wherein
each of the primary aging operation and the secondary aging operation includes high-temperature aging of aging the battery cell at a higher temperature than a temperature of the primary charging operation and low-temperature aging of aging the battery cell at a lower temperature than the high temperature, and at least a portion of the short time range overlaps the time range of the high-temperature aging and the time range of the low-temperature aging.

10. A system for detecting a defect of a battery in a formation process, the system comprising:
a measuring device configured to measure a voltage of a battery cell to undergo a formation process; and
a controller configured to analyze a difference between a pattern of the voltage and a reference pattern and detect a defect of the battery cell based on an analysis result,
wherein the controller analyzes the difference between the pattern of the voltage and the reference pattern within a short time range less than 1 day and a micro voltage range less than 1mV.

11. The system of claim 10, wherein
the pattern of the voltage includes at least one of a voltage variation during the time range or a voltage slope during the time range,
the reference pattern includes at least one of a reference variation or a reference slope, and
the controller analyzes at least one of a difference between the voltage variation and the reference variation or a difference between the voltage slope and the reference slope.

12. The system of claim 11, wherein
the measuring device measures each of a voltage at a start point and a voltage at an end point of the time range,
the controller generates information on whether the battery cell is defective, which is determined based on whether the difference between the voltage variation based on a voltage difference between the start point and the end point of the time range and the reference variation exceeds a variation error range,
the time range is more than 3 minutes and less than 3 hours, and
a maximum value of the variation error range is less than 0.3mV.

13. The system of claim 11, wherein
the measuring device measures each of a voltage at a start point and a voltage at an end point of the time range,
the controller generates information on whether the battery cell is defective, which is based on whether a difference between the voltage slope based on a voltage difference between the start point and the end point of the time range and the reference slope exceeds a slope error range, and
a maximum value of the slope error range is less than 0.1 (mV/hour).

14. The system of claim 10, further comprising:
a charger/discharger configured to perform press pre-charging (PPC) or pre-charging on the battery cell, and then perform formation-charging or formation charging/discharging on the battery cell after the PPC or pre-charging,
wherein the time range is after the PPC or pre-charging.

15. The system of claim 10, further comprising:
a temperature controller configured to increase or decrease a temperature of the battery cell,
wherein the time range includes a time point at which the temperature of the battery cell changes by the temperature controller.
